(19) United States
(12) Patent Application Publication
(10) Pub. No.: US 2007/0040722 A1
(43) Pub. Date: Feb. 22, 2007

(54) Display apparatus and control method thereof

(75) Inventor: Ung-jung Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/489,501

(22) Filed: Jul. 20, 2006

(30) Foreign Application Priority Data
Aug. 18, 2005 (KR) 2005-0075890

(51) Int. Cl. H03M 1/12

(52) U.S. Cl. 341/155

(57) ABSTRACT

A display apparatus including a signal converter which converts an input analog signal to a digital signal, and a display unit which displays an image. The apparatus comprises a signal analyzer for determining a format of the analog signal. An information inserter adds the determined format information to the digital signal. A video signal processor processes the digital signal according to the format information and outputting the processed signal to the display unit. Thus, the present invention provides a display apparatus for reducing error probability in a signal processing by discriminating a format of an input analog signal and adding information relating to the discriminated format to a digital signal, and a control method of the display apparatus.

### CROSS-REFERENCE TO RELATED APPLICATIONS

This application claims from the benefit under 35 U.S.C. §119(a) of Korean Patent Application No. 2005-0075890, filed on Aug. 18, 2005, in the Korean Intellectual Property Office, the entire disclosure of which is hereby incorporated by reference.

### BACKGROUND OF INVENTION

1. Field of Invention

The present invention relates to a display apparatus and a control method thereof. More particularly, the present invention relates to a display apparatus which receives an analog signal to convert it into a digital signal, and a control method thereof.

2. Description of the Related Art

A display apparatus receives an analog signal and/or digital signal, processes the received signal according to a display standard, and displays the processed signal as an image. Display apparatuses are generally provided with a digital processing block which processes a resolution and a frequency of an input signal by converting them according to the display standard. To process the signal, the digital processing block requires information relating to a format of the input signal.

When a digital signal is input, a header of a transmission packet provides information relating to a resolution, a frequency of the signal and so on. Hence, the digital processing block can process the input signal based on the information.

Meanwhile, when an analog signal is input, the display apparatus converts the received analog signal into a digital signal. As for the analog signal, information relating to a format of the signal is not separately provided.

Accordingly, a conventional display apparatus discriminates a format of an input signal by inferring an input resolution, and so on, based on horizontal and vertical synchronization signals (Hsync and Vsync) of the input signal. The discrimination of the signal format is carried out by a logic circuit which is hardware provided in the digital processing block or by the execution of a software program. According to the discriminated signal format, a central processing unit (CPU) in the digital processing block controls a digital processing module which includes a scaler, a decoder, IPC and the like, to process the signal in conformity with the standard of a display unit.

If a software program is used to discriminate the signal format, the CPU executes the software program. In this case, the coding is differentiated according to understanding degree of the signal by programs. Thus, if the signal is not fully understood, the signal format cannot be successfully discriminated and thus error may arise.

If the discrimination of the signal format is implemented by a hardware logic circuit, the digital processing block discriminates the signal format after a certain signal processing is conducted, for example, after the analog signal is converted into the digital signal. As a result, the format of the original analog signal may be not accurately discriminated.

Accordingly, there is a need for an improved display apparatus and control method for converting an input analog signal into a digital signal.

### SUMMARY OF THE INVENTION

It is an aspect of exemplary embodiments of the present invention to provide a display apparatus for reducing error probability in a signal processing by discriminating a format of an input analog signal and adding information relating to the discriminated format to a digital signal, and a control method of the display apparatus.

The foregoing and/or other aspects of exemplary embodiments of the present invention can be achieved by providing a display apparatus including a signal converter which converts an input analog signal into a digital signal, and a display unit which displays an image. The apparatus comprises a signal analyzer for determining a format of the analog signal. An information inserter adds the determined format information to the digital signal. A video signal processor processes the digital signal according to the format information and outputs the processed signal to the display unit.

According to an aspect of exemplary embodiments of the present invention, the format information includes at least one of resolution information and frequency information.

According to an aspect of exemplary embodiments of the present invention, the signal analyzer determines the format of the analog signal based on a synchronization signal of the analog signal.

According to an aspect of exemplary embodiments of the present invention, the signal analyzer comprises a logic circuit which counts the number of clocks of the synchronization signal of the analog signal.

According to an aspect of exemplary embodiments of the present invention, the video signal processor comprises at least one of a decoder, a scaler, a deinterlacer and a color converter for processing the digital signal.

According to an aspect of exemplary embodiments of the present invention, the video signal processor comprises a central processing unit (CPU) which controls at least one of the decoder, the scaler, the deinterlacer and the color converter to process the digital signal according to the formation information.

The foregoing and/or other aspects of exemplary embodiments of the present invention can be achieved by providing a control method of a display apparatus which includes a signal converter converting an input analog signal to a digital signal, and a display unit displaying an image. The method comprises determining a format of the analog signal; adding the determined format information to the digital signal; and processing the digital signal according to the format information and outputting the processed signal to the display unit.

According to an aspect of exemplary embodiments of the present invention, the format of the analog signal is determined based on a synchronization signal of the input analog signal.

According to an aspect of exemplary embodiments of the present invention, the format of the analog signal is determined based on a synchronization signal of the converted digital signal.

According to an aspect of exemplary embodiments of the present invention, the format of the analog signal is determined by counting the number of clocks of the synchronization signal of the analog signal.

According to an aspect of exemplary embodiments of the present invention, the format information is added to the digital signal by inserting the format information into a blank interval of the digital signal.

According to an aspect of exemplary embodiments of the present invention, the format information includes at least one of resolution information and frequency information.

According to an aspect of exemplary embodiments of the present invention, the processing of the digital signal comprises converting the digital signal based on the format information in conformity with an output standard of the display unit.

### BRIEF DESCRIPTION OF THE DRAWINGS

The above and/or other aspects and advantages of the prevent invention will become apparent and more readily appreciated from the following description of the exemplary embodiments, taken in conjunction with the accompany drawings, in which:

FIG. 1 is a block diagram of a display apparatus according to an embodiment of the present invention; and

FIG. 2 is a flowchart of an operation of the display apparatus according to an embodiment of the present invention.

Throughout the drawings, like reference numbers will be understood to refer to like elements, features and structures.

### DETAILED DESCRIPTION OF EXEMPLARY EMBODIMENTS

Reference will now be made in detail to exemplary embodiments of the present invention, which are illustrated in the accompanying drawings. The exemplary embodiments are described below so as to explain the present invention by referring to the figures.

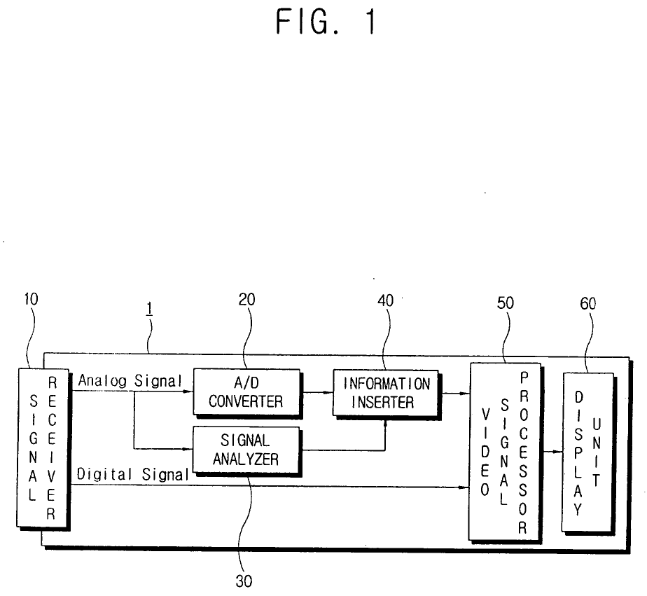

FIG. 1 is a block diagram of a display apparatus 1 according to an exemplary embodiment of the present invention. As shown in FIG. 1, the display apparatus 1 according to an exemplary embodiment of the present invention includes a signal receiver 10, an analog-to-digital (A/D) converter 20, a signal analyzer 30, an information inserter 40, a video signal processor 50 and a display unit 60.

The signal receiver 10 may include input terminals for a composite video baseband signal (CVBS), an S-video signal, a component signal, a PC-signal, a digital video/visual interactive (DVI) signal, and a high-definition multimedia interface (HDMI) signal, through which video signals corresponding to various external sources are received. In addition, the signal receiver 10 may include an antenna for receiving a broadcast signal, and a tuner for tuning a broadcast signal of a specific channel selected by a user.

As shown in FIG. 1, the received analog signal is converted to a digital signal by the A/D converter 20. The A/D converter 20 converts the received analog signal to the digital video signal by sampling the analog signal according to a clock signal having a certain frequency, and then outputs the converted signal.

A separator (not shown) may be provided to separate a synchronization signal from the received analog signal. The signal analyzer 30 discriminates a format of the received analog signal based on the separated synchronization signal.

The signal analyzer 30 may include a software program or a logic circuit which counts the number of clocks of the horizontal synchronization signal and/or the number of clocks between the vertical synchronization signals.

The signal analyzer 30 discriminates the format of the received analog signal based on the number counted by the logic circuit or the discrimination result produced by the execution of the software program, and then outputs information relating to the format.

As used herein, information relating to the format of the signal includes information relating to a resolution, a frequency and the like of the received analog signal.

The signal analyzer 30 discriminates the format of the signal by analyzing the analog signal prior to the A/D conversion as described above. In certain cases, the signal analyzer 30 may discriminate the format of the signal by analyzing the digital signal after the A/D conversion.

As such, the format of the signal is discriminated prior to the regular signal processing of the video signal processor 50, which is to be explained, so that the format of the signal can be relatively accurately discriminated. Therefore, the error probability can be lowered in the subsequent signal processing.

According to an exemplary embodiment of the present invention, the information inserter 40 inserts the format information of the signal output from the signal analyzer 30 into a blank interval of the digital signal which is output from the A/D converter 20. The information inserter 40 may be provided with a multiplexer (MUX). For instance, when the vertical resolution of the received analog signal is 480 i, the information inserter 40 inserts data of “0001” into the blank interval of the digital signal. As for the vertical resolution of 540 p and 1080 i, the information inserter 40 inserts data of “0010” and “1000” into the blank interval, respectively.

The video signal processor 50 processes the input digital signal in conformity with the standard of the display unit 60 according to the format information which is contained in the digital signal output from the information inserter 40. The display unit 60 may be applied to various display modules such as digital light processing (DLP), liquid crystal display (LCD), plasma display panel (PDP) and the like. The video signal processor 50 may include a scaler which converts the digital signal to match vertical frequency, resolution, and aspect ratio in accordance with a output standard of the display unit 60, a frame rate converter (FRC) which converts a frame rate, a color matrix converter which converts a color space, a MPEG-2 decoder, an analog decoder, and an IPC which converts an interlaced signal to a progressive signal.

The video signal processor 50 may further include a central processing unit (CPU). The CPU controls signal processing modules such as a scaler to process the input signal in conformity with the standard of the display unit 60 based on the format information contained in the digital signal.

For example, provided that the output resolution of the display unit 60 is 1080 i and the format information contained in the digital signal is 0001, the CPU sets a corresponding register value to up-convert 480 i to 1080 i so that the scaler can perform the signal processing accordingly.

In case that the output of the display unit 60 adopts a progressive scan, upon confirming that the input signal is the interlaced signal based on the input format information, the CPU controls the IPC to convert the interlaced signal to the progressive signal.

Furthermore, when the output frequency of the display unit 60 is 60 Hz and the vertical frequency of the input signal is 50 Hz according to the input format information, the CPU controls the FRC to convert the frame rate according to the output standard.

As such, the format information is added to the digital signal so that the video signal processor 50 can perform the signal processing based on the format of the input signal in conformity with the output standard of the display unit 60.

Therefore, the error probability in the signal processing can be reduced.

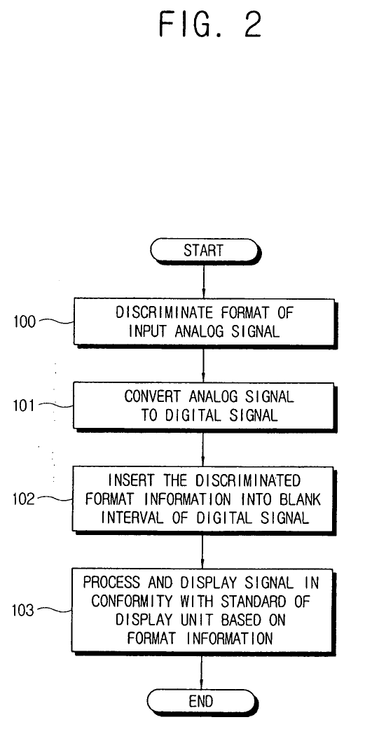

Hereafter, a control method of the display apparatus 1 is explained in reference to FIG. 2.

When an analog signal is input through the signal receiver 10, the signal analyzer 30 discriminates the signal format, such as frequency and resolution, of the input analog signal based on the synchronization signal separated from the input analog signal (100). The A/D converter 20 converts the input analog signal to a digital signal according to a certain clock signal (101).

The format information of the signal, which is discriminated by the signal analyzer 30, is inserted into a blank interval of the digital signal by the information inserter 40, and then the digital signal is output to the video signal processor 50 (102).

The video signal processor 50 confirms the format information contained in the input digital signal and processes the input digital signal based on the confirmed format information in conformity with the prescribed output standard of the display unit 60 (103).

Since the format of the signal is more accurately discriminated, the error probability can be reduced in the signal processing.

As set forth above, the display apparatus and the control method thereof can lower the error probability in the signal processing by discriminating the format of the input analog signal and adding the discriminated format information into the digital signal.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A display apparatus including a signal converter which converts an input analog signal to a digital signal, and a display unit which displays an image, the apparatus comprising:
a signal analyzer for determining a format of the analog signal;
an information inserter for adding the determined format information to the digital signal; and
a video signal processor for processing the digital signal according to the format information and outputting the processed signal to the display unit.

2. The display apparatus according to claim 1, wherein the format information includes at least one of resolution information and frequency information.

3. The display apparatus according to claim 2, wherein the signal analyzer determines the format of the analog signal based on a synchronization signal of the analog signal.

4. The display apparatus according to claim 3, wherein the signal analyzer comprises a logic circuit which counts the number of clocks of the synchronization signal of the analog signal.

5. The display apparatus according to claim 3, wherein the video signal processor comprises at least one of a decoder, a scaler, a deinterlacer and a color converter for processing the digital signal.

6. The display apparatus according to claim 5, wherein the video signal processor comprises a central processing unit (CPU) which controls at least one of the decoder, the scaler, the deinterlacer and the color converter to process the digital signal according to the formation information.

7. A control method of a display apparatus which includes a signal converter converting an input analog signal to a digital signal, and a display unit displaying an image, the method comprising the steps of:
determining a format of the analog signal;
adding the determined format information to the digital signal; and
processing the digital signal according to the format information and outputting the processed signal to the display unit.

8. The control method according to claim 7, wherein the format of the analog signal is determined based on a synchronization signal of the input analog signal.

9. The control method according to claim 7, wherein the format of the analog signal is determined based on a synchronization signal of the converted digital signal.

10. The control method according to claim 9, wherein the format of the analog signal is determined by counting the number of clocks of the synchronization signal of the analog signal.

11. The control method according to claim 10, wherein the format information is added to the digital signal by inserting the format information into a blank interval of the digital signal.

12. The control method according to claim 11, wherein the format information includes at least one of resolution information and frequency information.

13. The control method according to claim 12, wherein the processing step comprises:
converting the digital signal based on the format information in conformity with an output standard of the display unit.
